(19) United States
(12) Patent Application Publication
(10) Pub. No.: US 2017/0287752 A1
(43) Pub. Date: Oct. 5, 2017

(54) INTEGRATED METROLOGY AND PROCESS TOOL TO ENABLE LOCAL STRESS/OVERLAY CORRECTION

(71) Applicant: Applied Materials, Inc., Santa Clara, CA (US)

(72) Inventors: Ludovic GODET, Sunnyvale, CA (US); Mehdi VAEZ-IRAVANI, Los Gatos, CA (US); Todd EGAN, Fremont, CA (US); Mangesh BANGAR, San Jose, CA (US); Concetta RICCOBENE, Mountain View, CA (US); Abdul Aziz KHAJA, San Jose, CA (US); Srinivas D. NEMANI, Sunnyvale, CA (US); Ellie Y. YIEH, San Jose, CA (US); Sean S. KANG, San Ramon, CA (US)

(21) Appl. No.: 15/445,303

(22) Filed: Feb. 28, 2017

Related U.S. Application Data
(60) Provisional application No. 62/314,962, filed on Mar. 29, 2016.

(51) Int. Cl. H01L 21/67; H01L 21/265; H01L 21/66

(52) U.S. Cl. CPC H01L 21/67259; H01L 21/67196; H01L 21/67201; H01L 21/67213; H01L 21/67207; H01L 22/20; H01L 21/265; H01L 21/67167; H01L 21/67288

(57) ABSTRACT

Embodiments of the disclosure provide an integrated system for performing a measurement process and a lithographic overlay error correction process on a semiconductor substrate in a single processing system. In one embodiment, a processing system includes at least a load lock chamber, a transfer chamber coupled to the load lock chamber, an ion implantation processing chamber coupled to or in the transfer chamber, and a metrology tool coupled to the transfer chamber, wherein the metrology tool is adapted to obtain stress profile or an overlay error on a substrate disposed in the metrology tool.

### CROSS-REFERENCE TO RELATED APPLICATIONS

This application claims benefit of U.S. Provisional Application Ser. No. 62/314,962 filed Mar. 29, 2016 (Attorney Docket No. APPM/23850L), which is incorporated by reference in its entirety.

### BACKGROUND OF THE DISCLOSURE

### Field of the Disclosure

Embodiments of the disclosure generally relate to an integrated tool that includes at least a processing chamber and a metrology tool for lithography overlay correction, more specifically to an apparatus and methods for correcting unwanted curvature in a semiconductor substrate in a single processing system.

### Description of the Related Art

In the manufacture of integrated circuits (IC), or chips, patterns representing different layers of the chip are created by a chip designer. A series of reusable masks, or photomasks, are created from these patterns in order to transfer the design of each chip layer onto a semiconductor substrate during the manufacturing process. Mask pattern generation systems use precision lasers or electron beams to image the design of each layer of the chip onto a respective mask. The masks are then used much like photographic negatives to transfer the circuit patterns for each layer onto a semiconductor substrate. These layers are built up using a sequence of processes and translate into the tiny transistors and electrical circuits that comprise each completed chip. Typically, devices on semiconductor substrates are manufactured by a sequence of lithographic processing steps in which the devices are formed from a plurality of overlying layers, each having an individual pattern. Generally, a set of 15 to 100 masks is used to construct a chip and can be used repeatedly.

Between one layer and the next layer that overlays the previous one, the individual patterns of the one layer and the next layer must be aligned. However, due to pattern and material differences in the multiple overlying layers, film stress and/or topography variations (or pattern related differences) between layers is inevitable. The generated film stress between the layers formed on the substrate will cause the substrate to deform, which affects the lithographic patterning process results which can lead to device yield issues for the semiconductor devices formed on the substrate. Overlay errors of the device structure may originate from different error sources. One of sources commonly seen in the field is substrate film layer deformation caused by film stress, substrate curvature and the like. Film stress, substrate curvature, substrate deformation or surface topography variations of the device structure on the substrate may also result in displacement or misalignment of the lithographic patterns formed from one layer to the next, which may be detrimental to device yield results and/or cause variation in device performance.

FIGS. 1A-1B depict an example of a film layer 16 disposed on a substrate 15 which may be locally or globally deformed, or curved, after a sequence of device formation processes, which may affect the film stress or surface topography formed on the surface of the substrate 15. In FIG. 1A, the substrate 15 is deformed and curved, generating a curvature C1 in the substrate that has a first radius R1 globally across the back surface of the substrate 15. In addition to the global back surface curvature C1, local areas of the film layer 16 along with the substrate 15 may be deformed which creates localized curvature C2-C3 in the substrate 15 that are different from the back surface curvature C1. For example, in a close-up view of the local structures formed on the substrate 15, which are depicted in FIG. 1B, the substrate 15 has a varying curvature due to the pattern and residual stress formed within and/or between the film layer 16 and the substrate 15. The residual stress may be created during substrate processing steps due to differences in thermal expansion, plasma non-uniformity distribution and/or density during a plasma etching or plasma deposition processes, which results in the localized deformation of the substrate surface that creates the localized curvature C2 that has a second radius R2, which is different from the first radius R1 from the global surface curvature C1. The localized curvature C2 may also cause or be adjacent to an uneven surface region of the film layer 16 disposed on the substrate 15, leading to a localized curvature C3 that has a third radius R3 that may all be created by a stress S1 formed in the film layer 16. In the situation where the substrate 15 has a global curvature C1, conventional semiconductor formation processes have minimized the effect of the curvature C1 by clamping or restraining the substrate to a substrate support using a substrate holding device, such as an electrostatic chuck. However, in most of the situations, the process of clamping or restraining a substrate is not effective in reducing the localized curvatures C2-C3 formed in the substrate.

FIG. 2A depicts an overlay error map 100 of a semiconductor substrate measured after a sequence of processes that results in substrate deformation. In FIG. 2A, some of the patterns shown in an enlarged portion 102 of the substrate are shifted or displaced from their designed location. Displacement or misalignment of the patterns creates overlay errors that may be detrimental to device performance. A stress profile map 150 depicted in FIG. 2B also illustrates that substrate deformation and curvature not only generates the overlay errors, but also significantly influence the film stress distribution across the substrate 150. As shown in the stress profile map 150 depicted in FIG. 2B, a quite non-uniform film stress distribution is also observed across the substrate with one side 107 of the map 150 having a high stress level while another side 109 of the substrate having a relatively low stress level. Thus, the induced non-uniform stress distribution creates the substrate curvature or deformation which undesirably creates the overlay error. When overlay errors, or pattern displacement undesirably occurs, the size, dimension or structures of device dies formed on the substrate may be irregularly deformed or distorted, thus increasing likelihood of misalignment between the film layers stacked thereon that may adversely increase the probability of misalignment in the subsequent lithographic exposure process.

Moreover, with the push to shrink the critical dimensions (CD) of the semiconductor devices formed on the substrate, film stress/strain variations in the critical layers of the device structure must be minimized or eliminated in order to reliably produce devices that are nanometers in size. Thus, a correction process or a stress relieve process is desired in order to seek a proper solution to correct and relieve the localized curvature variations.

Therefore, there is a need for a system and method for detecting and correcting the localized deformation of a semiconductor substrate to eliminate overlay errors.

### SUMMARY

Embodiments of the disclosure provide an integrated system for performing a measurement process and a lithographic overlay error correction process on a semiconductor substrate in a single processing system. In one embodiment, a processing system includes at least a load lock chamber, a transfer chamber coupled to the load lock chamber, an ion implantation processing chamber coupled to the transfer chamber, and a metrology tool coupled to or in the transfer chamber, wherein the metrology tool is adapted to obtain stress profile or an overlay error on a substrate disposed in the metrology tool.

In another embodiment, a method for correcting stress profile or overlay error on a substrate includes performing a measurement process in a metrology tool disposed in a processing system on a substrate to obtain a substrate distortion or an overlay error map, determining a surface modification recipe in a computing system based on the substrate distortion or overlay error map obtained from the measurement process in the processing system, and performing an ion implantation process in a processing chamber disposed in the processing system to correct substrate distortion or overlay error on the substrate.

In yet another embodiment, a method for correcting overlay error on a substrate includes measuring a film stress of a substrate disposed in a metrology tool in a processing system, creating a correlation to the film stress behavior with a database library to determine an ion implantation recipe, and performing an ion implantation process on selected discrete locations of the substrate using the determined ion implantation recipe in a processing chamber disposed in the processing system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings.

FIGS. 1A-1B depict a cross sectional view of a substrate with curvature formed in the substrate;

FIG. 2A depicts an overlay error map of a semiconductor substrate with curvature;

FIG. 2B depicts a stress profile map of a semiconductor substrate with curvature;

FIG. 3 depicts one example of an processing chamber which may be utilized to provide dopants into a semiconductor substrate to perform a substrate curvature or stress correction process;

FIG. 4 is a schematic side view of a portion of a processing chamber which may be utilized to provide dopants into a semiconductor substrate to perform a substrate curvature or stress correction process;

FIG. 5 is a schematic plan view of substrate that is receiving at least a portion of substrate curvature or stress correction process performed thereon, according to an embodiment described herein;

FIG. 6A is a schematic side cross-sectional view of a beam source assembly that is adapted to provide multiple beams to a substrate for performing a substrate curvature or stress correction process, according to an embodiment described herein.

FIG. 6B is a plot of the beam distribution as a function of angle for the beams delivered from a beam source assembly illustrated in FIG. 6A, according to an embodiment described herein.

FIG. 6C is a schematic side cross-sectional view of a beam source assembly that is adapted to provide multiple beams, according to an embodiment described herein.

FIG. 6D is a plot of the beam distribution as a function of angle for the beams delivered from the beam source assembly illustrated in FIG. 6C, according to an embodiment described herein;

FIG. 7 is a plot of a beam modification profile as a function of depth in a surface of the substrate, according to an embodiment described herein.

FIG. 8 is a plan view of a cluster tool including a processing chamber that may perform a substrate curvature or stress correction process in accordance with one embodiment of the present disclosure;

FIG. 9 depicts a flow diagram of a method for performing an overlay correction process on a film layer deposited on a semiconductor substrate utilizing an ion implantation process; and

FIG. 10A-10B depicts an overlay error map and a stress distribution profile map respectively after a stress or correction process is performed on the substrate.

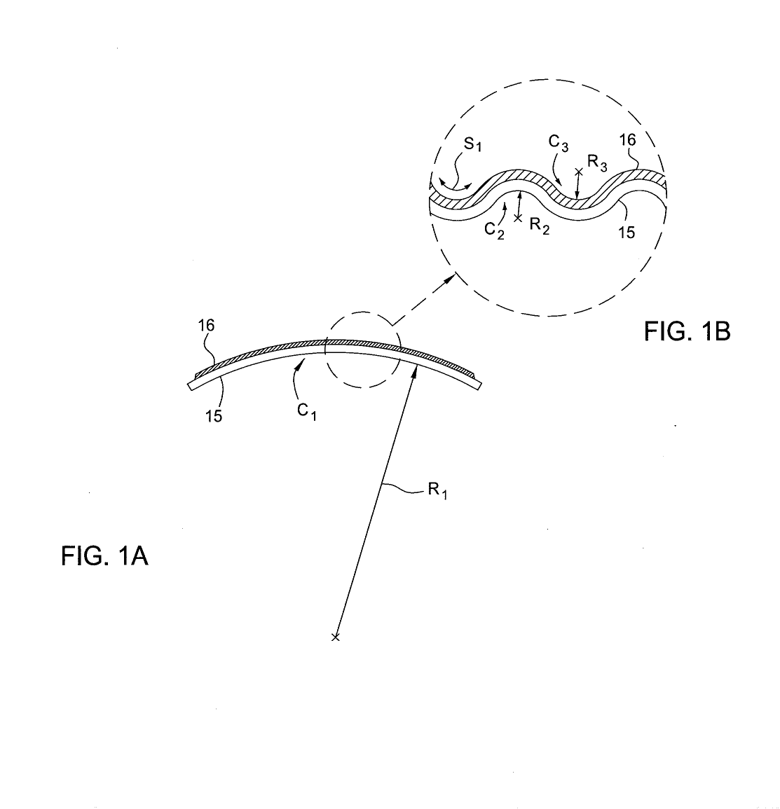

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this disclosure and are therefore not to be considered limiting of its scope, for the disclosure may admit to other equally effective embodiments.

### DETAILED DESCRIPTION

Embodiments of the disclosure describe an overlay error or stress distribution correction process that may be utilized to correct film stress or minimize overlay errors resulting from the deformation or induced curvature of a substrate. In one embodiment, the stress or overlay correction process is a film modification process includes a process of delivering a form of energy or beam, such as an ion implantation process, to a region of a substrate. The process of modifying a substrate generally includes the alteration of a physical or chemical property of the substrate and/or redistribution of a portion of an exposed material on the substrate by use of one or more energetic beams while the substrate is disposed within a film modification apparatus. In one example, the surface modification process is performed by utilizing an ion implantation process to dose ions to a film layer to alter film stress/strain in the film layer disposed on the semiconductor substrate. By establishing an algorithm that may compute the amount of ion dose required to correct the film layers on the semiconductor substrate, the overlay error may be corrected and eliminated so as to increase alignment precision for the next lithographic exposure process. During the operation, the substrate may be transferred to a processing system that includes at least an ion implantation apparatus, a metrology tool and optionally a plasma processing chamber. The substrate may optionally first have a film layer (or a multi-layered film stack) formed on the substrate. Subsequently, the substrate may be transferred to the metrology system incorporated in the processing system to perform a measurement process to obtain a stress profile map, and/or a substrate deformation map, and/or an overlay error map. After analysis and calculations based on the stress profile map and/or the overlay error map obtained, a surface modification process may be performed in the ion implantation apparatus to correct localized stress profile of the substrate to reduce overlay error during the subsequent lithographic exposure process. The ion implantation apparatus, the measurement tool and optionally a plasma processing chamber may be incorporated in a single processing system that may perform all processes (including the film layer deposition process, measurement process and the surface modification process) in one processing system without breaking vacuum.

In one example, the film modification process may include performing one or more steps that preferentially alter the physical and/or chemical properties of the material on an outer surface of a substrate. In some embodiments, the film modification process is used to alter the properties of the material on select surfaces that are positioned in a desired orientation relative to the incoming beam. Selectively modifying the surface of the substrate or material deposited thereon enables the treated material to be removed from, or remain on, the surface of the substrate. The modification process may include implanting a particular element within selected regions on the surface of the substrate to alter the composition, chemical structure and/or physical structure (e.g., crystal structure, density, grain size, roughness, etc.) of the substrate of material deposited thereon.

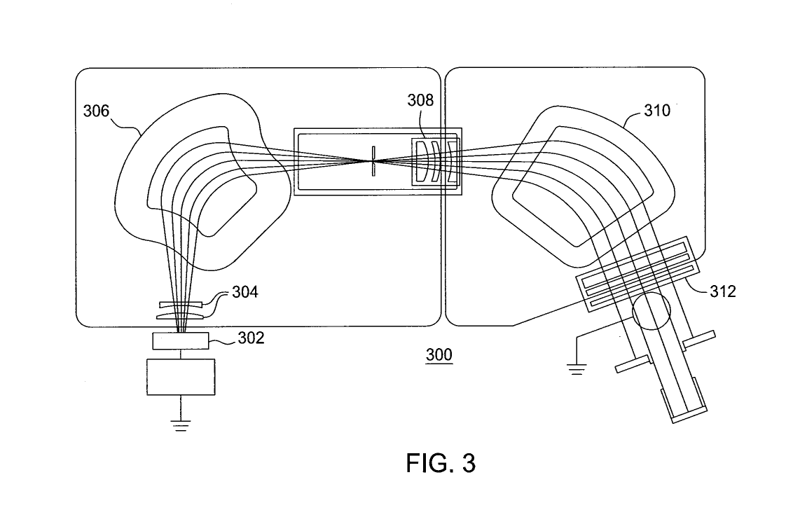

FIG. 3 depicts an ion implanting processing chamber 300 that may be utilized to dope ions into certain regions of the substrate. The ion implanting processing chamber 300 includes an ion source 302, extraction electrodes 304, a 90 degree magnet analyzer 306, a first deceleration (D1) stage 308, a magnet analyzer 310, and a second deceleration (D2) stage 312. The deceleration stages D1, D2 (also known as “deceleration lenses”) are each comprised of multiple electrodes with a defined aperture to allow an ion beam to pass therethrough. By applying different combinations of voltage potentials to the multiple electrodes, the deceleration lenses D1, D2 can manipulate ion energies and cause the ion beam to hit a target wafer at a desired energy which implants ions into a substrate. The above-mentioned deceleration lenses D1, D2 are typically electrostatic triode (or tetrode) deceleration lenses.

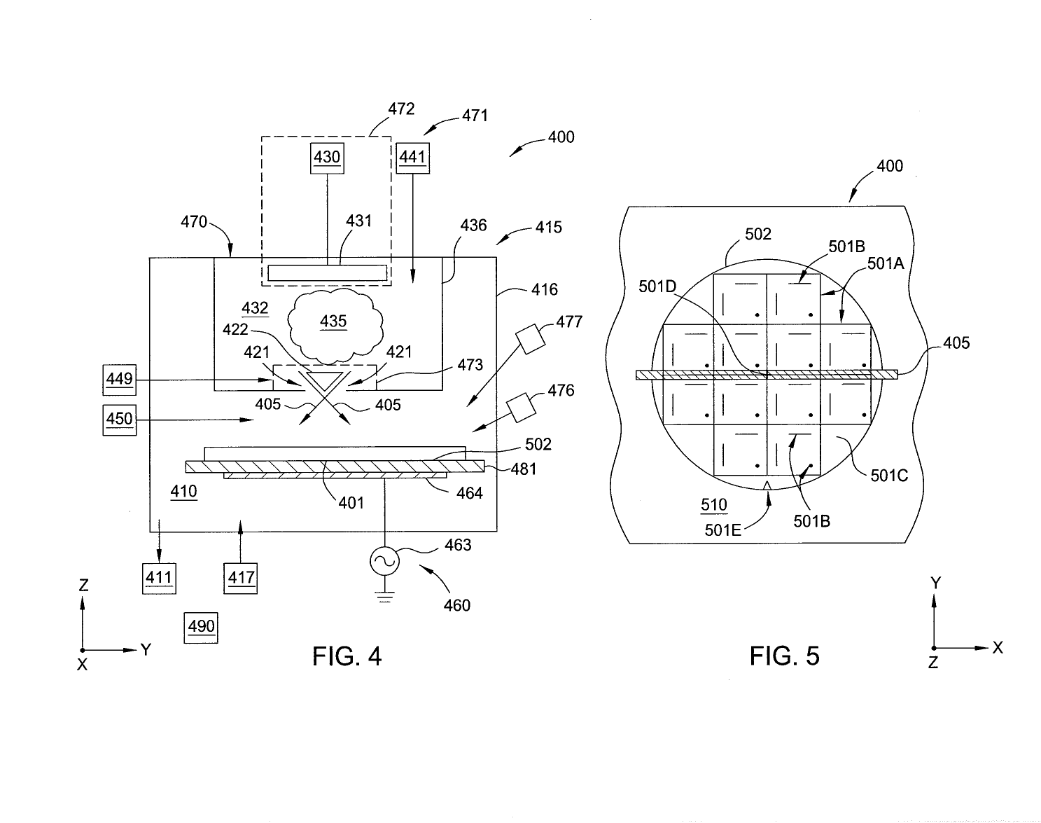

FIG. 4 is a schematic cross-sectional view of a processing chamber 400 that may be adapted to perform a film modification process, such as an ion implantation process, that may be utilized to correct film stress or overlay errors on a substrate. The processing chamber 400 is an ion implantation processing chamber that includes a beam source assembly 470 that is positioned to modify a portion of a substrate 502. The processing chamber 400 generally includes a chamber assembly 415 and the beam source assembly 470. The chamber assembly 415 generally includes one or more walls 416 that enclose the processing region 410 in which the substrate 502 is disposed during the surface modification process. The chamber assembly 415 will also typically include a system controller 490, a pumping system 411 and a gas delivery source 417, which are used in combination to control the processing environment within the processing region 410. The pumping system 411 may include one or more mechanical pumps (e.g., rough pump, turbo pump) that are configured to control a desired pressure within the processing region 410. The gas delivery source 417 may include one or more sources that are configured to deliver an amount or a flow of an inert and/or a reactive gas (e.g., etchant gases) to the processing region 410. In some configurations, the chamber assembly 415 may also include a thermal source (not shown), e.g., lamps, radiant heaters, that is controlled by the system controller 490 to adjust the temperature of the substrate 502 during processing. In one example, the system controller 490 is configured to control the gas composition, chamber pressure, substrate temperature, gas flow or other useful process parameter in the processing region 410 during the surface modification process.

The chamber assembly 415 will also include a substrate support assembly 481 that is adapted to support the substrate 502 during processing. The substrate support assembly 481 may include one or more actuators (not shown) that are adapted to translate or rotate the substrate 502 relative to the electrode assembly 473 during processing. In applications that require the substrate 502 to be translated or rotated, some of the driving components, such as an actuator or a motor are positioned outside of the processing region 410 and are coupled to the elements that support the substrate 502 within the processing region 410 using a conventional vacuum feed-through or other similar mechanical device. In some configurations, one or more of the actuators are adapted to position the substrate 502 relative to the electrode assembly 473 so that a desired gap (not shown), which is measured in the Z-direction in FIG. 4, is formed between the substrate 502 and the electrode assembly 473.

In one example, the beam source assembly 470 typically includes a gas source 471, a plasma generation source 472 and electrode assembly 473. In one configuration, as illustrated in FIG. 4, the gas source 471 generally includes one or more separate gas sources 441 that are each configured to deliver a process gas (e.g., gas atoms, gas phase molecules or other vapor containing materials) to the plasma generation region 432 of the beam source assembly 470. The plasma generation region 432 may be bounded by walls 436. In one example, the gas source 441 is configured to deliver a process gas that includes a gas selected from the group consisting of carbon (C), silicon (Si), oxygen (O₂), NO₂, N₂O, CO, CO₂, argon (Ar), neon (Ne), krypton (Kr), xenon (Xe), radon (Rn), nitrogen (N), helium (He), hydrogen (H₂), chlorine (Cl₂), fluorine (F₂), bromine (Br₂), iodine (I₂), ammonia (NH₃) and/or combinations thereof to the plasma generation region 432.

The pumping system 411 may also be separately connected to the processing region 410 and the plasma generation region 432 so that different pressures can be maintained in each region. In one example, the pumping system 411, gas delivery source 417 and/or gas sources 441 are configured to work together to maintain the plasma generation region 432 at a pressure greater than the processing region 410 during processing. In one configuration, the plasma generation region 432 includes a pump (not shown) that is separate from the pumping system 411, and is configured to maintain the pressure in the plasma generation region 432 at a desired level.

The plasma generation source 472 generally includes a source of electromagnetic energy that is configured to form a plasma 435 in the plasma generation region 432 using the process gas delivered from the one or more gas sources 441. The plasma generation source 472 may include a power source 430 and an antenna 431, which is in electrical communication with the plasma generation region 432. In one non-limiting example, the antenna 431 may be a capacitively coupled electrode that is adapted to generate the plasma 435 in the plasma generation region 432, when radio frequency (RF) energy is delivered from the power source 430 to the antenna 431 during processing.

The electrode assembly 473 may include a beam controller 449 and beam delivery element 422 that are used to extract ions formed within the plasma generation region 432 to form and deliver one or more energetic beams 405 to a surface of the substrate 502 through one or more apertures 421 that are formed in the beam delivery element 422. The shape of the aperture 421 is formed so that a beam having a desired shape is created by the beam delivery element 422, such as a ribbon shaped or cylindrical shaped beam. In some configurations, the aperture 421 is also positioned and aligned to direct the beam 405 to a desired portion or region of the surface of the substrate 502 during processing. The system controller 490 is generally configured to control the generation and delivery of the one or more energetic beams 405 by sending commands to the various components found in the beam controller 449 and beam delivery element 422. The beam delivery element 422, which is coupled to the beam controller 449, may include a “triode” assembly that is configured to extract ions generated in the plasma generation region 432 of the plasma generation source 472 and form and deliver an energetic beam 405 to desired region of a surface of a substrate 502 through an aperture 421 formed in the beam delivery element 422. In operation, a triode assembly will contain a first electrode, a second electrode, and a third electrode that are independently biased, such that the properties of the beam 405, such as beam energy (e.g., kinetic energy) and direction, can be controlled. Since it may be possible to form positive or negative ions in the plasma 435 the biases applied to the various electrodes may be adjusted accordingly to generate and deliver a beam 405 having a desired composition and energy to the surface of the substrate 502. In some embodiments, the particles (e.g., charged particles or neutrals) in the beam 405 are delivered to the surface of the substrate at an energy of, for example, approximately 0.1 keV to 20 keV.

The chamber assembly 415 may include a bias assembly 460 that is in communication with the system controller 490 and is configured to deliver energy to the processing region 410 of the processing chamber 400. The bias assembly 460 generally includes a support electrode 464 and a source 463, which is coupled to ground and can be used to remove any accumulated charge found on the substrate 502 during or after performing the film modification process. To remove any residual charge found on the substrate, the source 463 may utilize an AC or high frequency power source (e.g., 40 kHz-200 MHz power source) that is configured to form a plasma over the substrate 502 during one or more phases of the plasma modification process performed in the processing region 410. It is believed that the formed plasma will provide a path to ground that will allow any stored charge in the substrate to be dissipated. In some cases the bias assembly 460 can also be used to help control the trajectory and/or energy of the beam 405 that strikes the surface of the substrate 502 during the film modification process.

In some embodiments, the chamber 400 may also include a reactant source 450 that is configured to deliver a reactant gas to the region of the surface of the substrate that is to receive, or is receiving, the generated beam 405. In one configuration, the reactant source is a remote plasma source (RPS) that is configured to provide an ion, a radical and/or a neutral containing gas to the surface of the substrate to promote the modification and/or removal of a portion of the material from the surface of the substrate. The RPS may include a capacitively coupled, inductively coupled or microwave type source that is adapted to generate ions or radicals within a process gas that is delivered through a portion of the RPS assembly from a gas source.

FIG. 5 is a plan view of the substrate 502 that is disposed within the processing region 410 of the processing chamber 400. The substrate 502 may include a plurality of die 501A that contain a plurality of features 501B formed therein. The plurality of die 501A are aligned relative to an alignment mark and notch 501E of the substrate 502. The features 501B, which, for example, may have an undesirable curvature, will generally include protrusions and depressions in the non-planar surface 501C of the substrate 502, which are to be selectively modified using the processes described herein to correct film stress and/or overlay errors. The features 501B are only provided as examples of features that may be modified using processes described herein.

In some embodiments of the processing chamber 400, a substrate inspection module 477 (FIG. 4) is used to inspect and orient the substrate 502, and thus features 501B, relative to the beam source assembly 470, so that the beam can be directed to modify only the features 501B that are desirably oriented on the substrate 502. It is noted that the modified map may be obtained by an overlay error map, substrate curvature or stress distribution map measured from a metrology tool, which is discussed further below.

In general, the inspection and alignment device may include a processing chamber camera (not shown (e.g., CCD camera)) and one or more actuators (not shown), such as an X-Y stage with a rotational actuator (about Z-direction). The processing chamber camera and the one or more actuators are in communication with the system controller 490, so that the system controller 490 can provide instructions to various components in the system to reorient and/or reposition (e.g., angular and/or X-Y position (FIG. 5)) the substrate based on the data received from the overlay error map created by the metrology tool and by the processing chamber camera and the control of the one or more actuators. The one or more actuators can be coupled to the substrate supporting elements, such as the substrate support assembly 481. The inspection module 477 can also be configured to determine an orientation of a substrate and provide information relating to the determined orientation to the system controller, so that the system controller can cause the substrate transferring components (e.g., robots, X-Y stages) to position the substrate on the substrate supporting surface in the processing chamber in a desired orientation relative to the relative movement of the substrate during processing, or beam source assembly 470, based on the provided information.

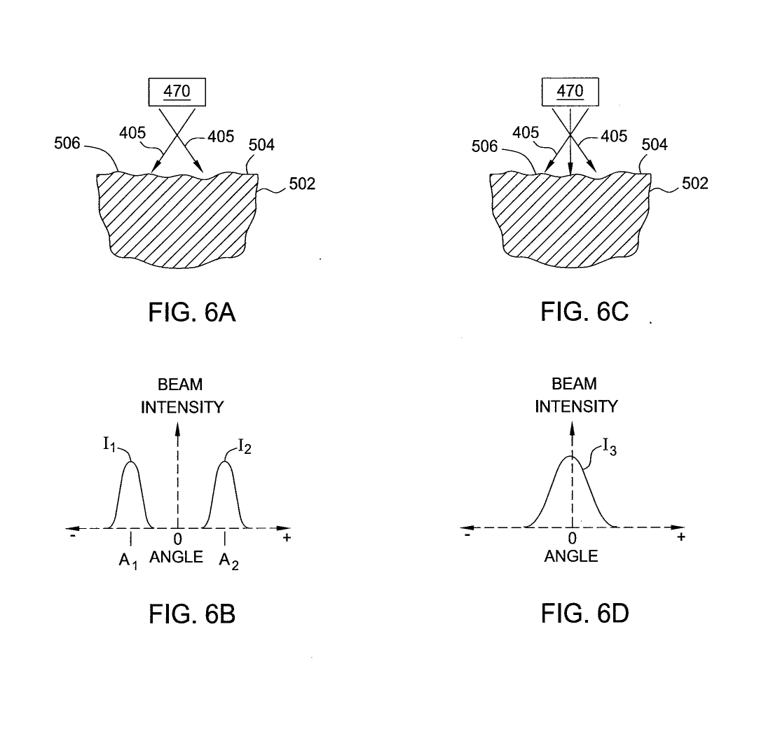

In one configuration, as illustrated in FIG. 5, a single ribbon shaped beam 405 is oriented and delivered across the surface of the substrate 502 to modify portions of the surface 501C of the substrate 502. In some embodiments, the beam 405 is maintained at a desired preferred angle relative to surface of the substrate 502 to assure that the layout, orientation or directional nature of plurality of the generated beam(s) 405 can be used to modify certain features that are aligned in a certain direction relative to the substrate surface, such as discussed in conjunction with FIGS. 6A-6D below. In one example, as illustrated in FIGS. 5 and 6B, the beam source assembly 470 is configured to deliver a ribbon shaped beam (e.g., an ion beam 405) that is provided parallel to the X-Z plane and at a grazing angle to the substrate. In this configuration, the processing chamber 400 may include a translating substrate support assembly 481 that is configured to position, support and transfer the substrate 502 relative to the ion beam 405 when the substrate 502 is disposed within the processing region 410. By varying the position of the substrate 502 relative to the ion beam 405, only regions that have a certain orientation relative to the ion beam will be modified, due to the directional nature of the incident ion beam 405. The translating substrate support assembly 481 is configured to translate the substrate 502 in a direction that is at an angle to the direction that the ion beam(s) 405 are being delivered, so that only features that are oriented in a certain way on the surface of the substrate are modified by the delivered ion beam(s). In general, the angle between the translation direction and beam direction will be a non-zero and non-parallel angle. In some embodiments, the substrate 502 is maintained in a fixed orientation relative to the delivered ion beam 405 and/or translation direction. In one example, the translating substrate support assembly 481 is configured to translate the substrate 502 in a direction that is substantially perpendicular to the direction that an ion beam is delivered. In this example, the translating substrate support assembly 481 may be configured to translate the substrate in the Y-direction, while a grazing angle beam that is provided in the X-Z plane (FIG. 5) is delivered to the surface of the substrate that has fixed orientation within the X-Y plane.

In one example, as illustrated in FIG. 6A, the ion beam source assembly 470 may be configured to deliver at least two ion beams 405 that are delivered in different directions, such as opposing directions (i.e., −X and +X-directions). As illustrated in FIG. 6B, the beam source assembly 470 may be configured to deliver two beams 405 in a bi-modal distribution, where the distribution of the energetic particles provided in each of the ion beams 405 (i.e., beam intensity I₁ and I₂) is directed at a preferred angle, such as angle A₁ for the +X-direction ion beam 405 and angle A₂ for the −X-direction ion beam 405.

In another configuration illustrated in FIG. 6C, the beam source assembly 470 may be configured to deliver at least three ion beams 405 that are each delivered in different directions. As shown, three ion beams 405 are delivered in the −X-direction, +X-direction and normal direction. As illustrated in FIG. 6D, the intensity of the sum of the effects of the multiple ion beams provided by the beam source assembly 470 is configured to deliver a broader beam energy distribution, where the distribution of the energetic ions provided from the ion beams 405 has an averaged shape as shown by the beam intensity I₃. By varying the energy provided by the different ion beams, the shape of the distribution can be altered to improve some aspect of the beam modification process.

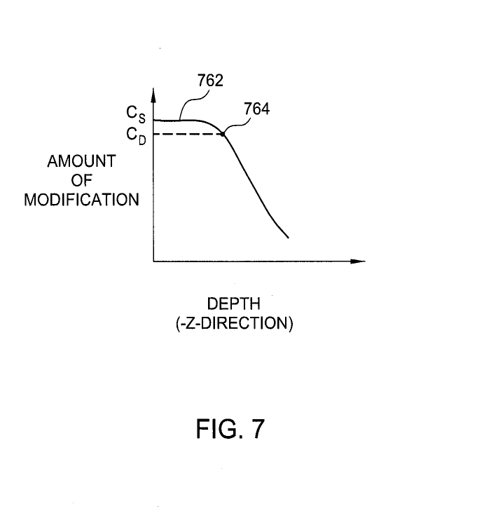

FIG. 7 is a plot of a modified material profile 762 plotted vertically from a surface extending down into the substrate 502. The modified material profile is a graphical representation of the amount of modification applied to the surface of the substrate 502 as a function of depth. By controlling the beam parameters and time that the surface of the substrate 502 is exposed to the ion beam 405, a desired modified material profile (such as stress alternation process, substrate distortion, or overlay error change) can be achieved within the surface of the substrate so as to correct the localized stress level or substrate distortion formed at certain locations in the substrate 502. In one example, where the film modification process is adjusted to implant an element or molecule into the surface of the substrate, the modified material profile represents the concentration of the implanted element as a function of depth (e.g., atoms/cm³). Thus, in some cases, where the surface of the substrate comprises silicon (Si), doped silicon (e.g., n-type or p-type), silicon oxide (SiOₓ), silicon nitride (SiN) or other useful silicon compound, the implanted element may include hydrogen (Hₓ or Hₓ⁺) or dopant atoms (e.g., boron (B), gallium (Ga), phosphorous (P), arsenic (As), etc.) that preferentially alter the surface of the substrate 502, and/or any film(s) thereon. In one example, the surface of the substrate comprises a carbon (C) containing layer, such as an amorphous carbon layer, and the implanted element may include carbon that preferentially alters an undesirable curvature formed in the surface of the substrate 502. Alternatively, in one example, the surface modification process is adjusted to primarily alter the physical structure of the material at the surface of the substrate (e.g., amorphize, alter crystal structure), by directing the beam containing a gas or molecule to the surface of the substrate, and thus the modified material profile illustrated in FIG. 7 represents the concentration of the altered physical structure as a function of depth (e.g., thickness of amorphous region, defects/cm³, dislocations/cm³, etc). Thus, in some cases, the ion beam 405 may include an inert gas, such as oxygen (O₂), carbon containing gas, silicon containing gas, argon (Ar), neon (Ne), krypton (Kr), xenon (Xe), radon (Rn), nitrogen (N), helium (He) or a combination thereof. However, in some cases, the ion beam 405 may include an ion that is similar to the materials found in the layer that is to receive the ion beam dose. Thus, in this case, the process of altering the physical structure of the material will not change or adversely affect the chemical bonding or chemical structure of the layer.

The modified material profile 762 in general will have a surface concentration C_{S} and a critical dose concentration C_{D}, where concentration levels of the modified parameter (e.g., concentration of the implanted element, concentration of defects, etc.) that are equal to or greater than the critical dose C_{D}, which defines the depth of the modified area from the substrate 502. In general, if a negative modification process is used, the critical dose C_{D} will define the depth of the material that will be removed during the modification process. It is desirable for the slope of the modified material profile as a function of depth to be steep after the critical dose (C_{D}) level 764 has been reached. In general, the critical dose C_{D} amount at the critical dose level 764 will vary depending on the properties of the material and the level of the stress/strain in the film to be altered.

By obtaining the relationship/correlation of the film stress (or in-plane strain, pattern shift, or substrate curvature) to the ion implantation concentration dose required to correct the substrate, a database library may be established. As such, the residual film stress at discrete localized areas of the film layer may be corrected or released based on the computation/calculation from the database library, so as to reduce/correct overlay errors that might be present on the substrate and enhance alignment precision of a subsequent lithographic exposure process. It is noted that the database may be stored in a data computing system in a metrology tool or a controller where the metrology tool is coupled to or integrated to.

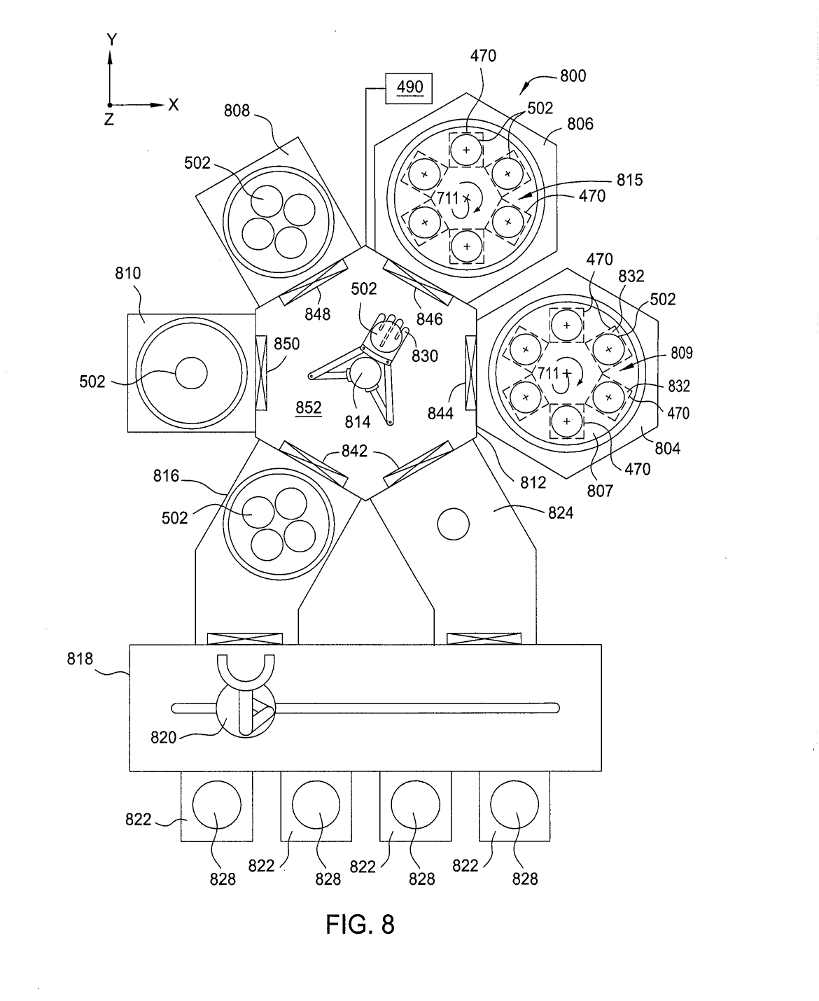

FIG. 8 is a plan view of a processing system 800 that incorporates both a metrology tool and a surface modification tool, such as an ion implantation chamber 400 depicted in FIG. 3, so as to perform a measurement process and a stress or overlay error correction process in a single process system. The processing system 800 generally creates a processing environment where various processes can be performed on a substrate, such as a stress and/or overlay measurement process and the surface modification process. The processing system 800 generally include the system controller 490 programmed to carry out various processes performed in the processing system 800.

The system controller 490 may be used to control one or more components found in the processing system 800. In some configurations, the system controller 490 may form part of the system controller 490, which is discussed above with reference to FIG. 4. The system controller 490 is generally designed to facilitate the control and automation of the processing system 800 and typically includes a central processing unit (CPU) (not shown), memory (not shown), and support circuits (or I/O) (not shown). The CPU may be one of any form of computer processors that are used in industrial settings for controlling various system functions, substrate movement, chamber processes, and control support hardware (e.g., sensors, robots, motors, lamps, etc.), and monitor the processes performed in the system (e.g., substrate support temperature, power supply variables, chamber process time, I/O signals, etc.). The memory is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits are also connected to the CPU for supporting the processor in a conventional manner. The support circuits may include cache, power supplies, clock circuits, input/output circuitry, subsystems, and the like. A program (or computer instructions) readable by the system controller 490 determines which tasks are performable on a substrate in one or more of the process chambers and in the processing system 1000. Preferably, the program is software readable by the system controller 390 that includes code to perform tasks relating to monitoring, execution and control of the movement, support, and/or positioning of a substrate along with the various process recipe tasks and various chamber process recipe steps being performed in the processing system 800.

The processing system 800 includes a plurality of processing chambers 804, 806, 808 and at least one metrology tool 810 that are coupled to a transfer chamber 812. Each processing chamber 804, 806, 808 and the metrology tool 810 may be configured to process and/or measure one or more substrates 502 at a time. The processing chamber 804, 806, 808 and the metrology tool 810 may have the same or different substrate processing or measurement capacities. For example, the processing chamber 804 and 806 can simultaneously process six substrates, while processing chambers 808 and the measurement tool 810 may be adapted to process one or more substrates at a time.

The processing system 800 may also include load lock chambers 816 and 824 that are connected to the transfer chamber 812. In one embodiment, the load lock chambers 816 and 824 may also be used as one or more service chambers for providing various functions for processing within the processing system 800, for example, substrate orientation, substrate inspection, heating, cooling, degassing, or the like.

In one embodiment, the load lock chambers 816, 824 or the factory interface 818, include a substrate inspection assembly (e.g., inspection module 477) that is able to detect the position and orientation of a substrate (e.g., substrate notch) relative to one or more features within the system. In some cases, the substrate inspection assembly is configured to detect the substrate's current position and orientation and then reposition and reorient the substrate so that it can then be correctly positioned and oriented in one of the processing chambers 804, 806, 808, 810 by the processing system's robotic elements. The substrate inspection assembly can thus be used to at least orient the substrate so that the surface modification process can be desirably aligned to the features formed the surface of the substrate.

The transfer chamber 812 defines a transfer volume 852. A substrate transfer robot 814 is disposed in the transfer volume 852 for transferring substrates 502 among the processing chamber 804, 806, 808, the metrology tool 810 and the load lock chambers 816 or 824. The transfer volume 852 is in selective fluid communication with the processing chamber 804, 806, 808, the metrology tool 810 and the load lock chambers 816 and 824 via slit valves 844, 846, 848, 850, 842 respectively. In one example, the transfer volume 852 may be maintained at a sub-atmospheric pressure while the substrates are transferred through the processing system 800.

The processing system 800 includes a factory interface 818 connecting one or more pod loaders 822 and the load lock chambers 816 and 824. The load lock chambers 816 and 824 provides a first vacuum interface between the factory interface 818 and the transfer chamber 812, which may be maintained in a vacuum state during processing. Each pod loader 822 is configured to accommodate a cassette 828 for holding and transferring a plurality of substrates. The factory interface 818 includes a FI robot 820 configured to shuttle substrates between the load lock chambers 816 and 824, and the one or more pod loaders 822.

The substrate transfer robot 814 includes a robot blade 830 for carrying one or more substrates 502 among the processing chamber 804, 806, 808, the metrology tool 810, the load lock chamber 816 and 824, and loading/unloading each chamber.

Each processing chamber 804, 806, 808 may be configured to perform plasma processing chambers, such as a film deposition chamber, and the surface modification process described herein and the metrology tool 810 may be configured to perform a stress or overlay error measurement process prior to and/or after the substrate modification process is performed on the substrate. In one embodiment of the processing system 800, the process chambers 804 and 806 are adapted to perform the surface modification process on a plurality of substrates using a plurality of beam source assemblies 470. The processing chamber 808 may be adapted to be a film deposition chamber configured to form a film layer on the substrate 502. The process chambers 804 and 806 will generally contain some or all of the process chamber hardware components discuss above in conjunction with FIG. 4, particularly.

In one configuration of the processing system 800, the processing chambers 804 and 806 each include a substrate conveyance assembly 807 that is configured to retain and transport a plurality of substrates 502 that are retained within the processing regions 809 or 815 of the processing chambers 804 or 806, respectively. In one example, each of the substrate conveyance assemblies 807 are adapted to retain six substrates 502 and rotate the substrates 502 about a central axis 711 of the processing chamber 804 or 806 by use of conventional rotational hardware components. The substrate conveyance assembly 807 is thus able to transfer and position the substrates 502 relative to each of the beam source assemblies 470 that are positioned to process substrates 502 found in the processing region 809 or 815 of the processing chamber 804 or 806, respectively.

In some configurations of processing chamber 804, each of the substrates 502 that are disposed on the substrate conveyance assembly 807 can be separately moved relative to the beam source assembly 470 by use of a substrate rotation assembly 832. In this case, the substrate rotation assembly 832 generally includes an actuator (not shown) that is configured to separately directionally translate, position and/or orient a substrate supporting element (not shown), which a substrate rests on during processing, relative to the substrate conveyance assembly 807.

However, in some embodiments, the ion beam 405 generated by each beam source assembly 470 may be translated relative to the surface of the substrate (e.g., X-Y plane). In this case, an actuator (not shown) that is found within each beam source assembly 470 is configured to translate and/or orient the beam delivery element 422 (FIG. 4) relative to the substrate to assure the complete processing of the surface of the substrate.

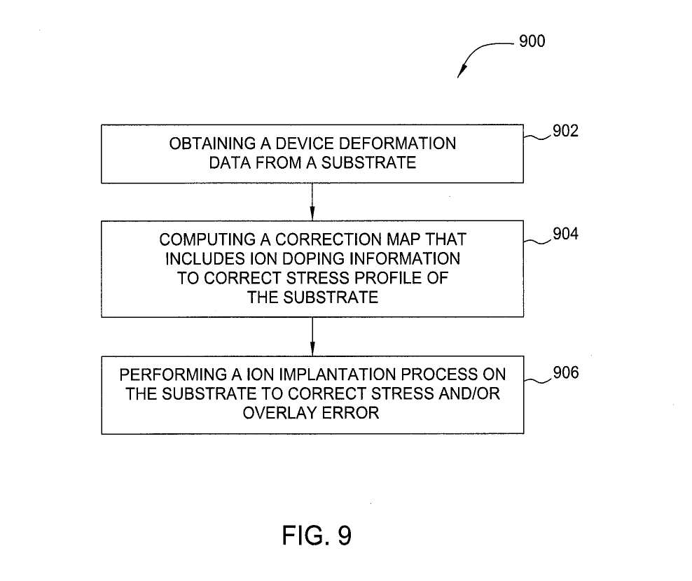

FIG. 9 depicts a flow diagram of a process 900 for performing an integrated measurement and stress/overlay correction process on a semiconductor substrate in an integrated processing system by utilizing a surface modification process.

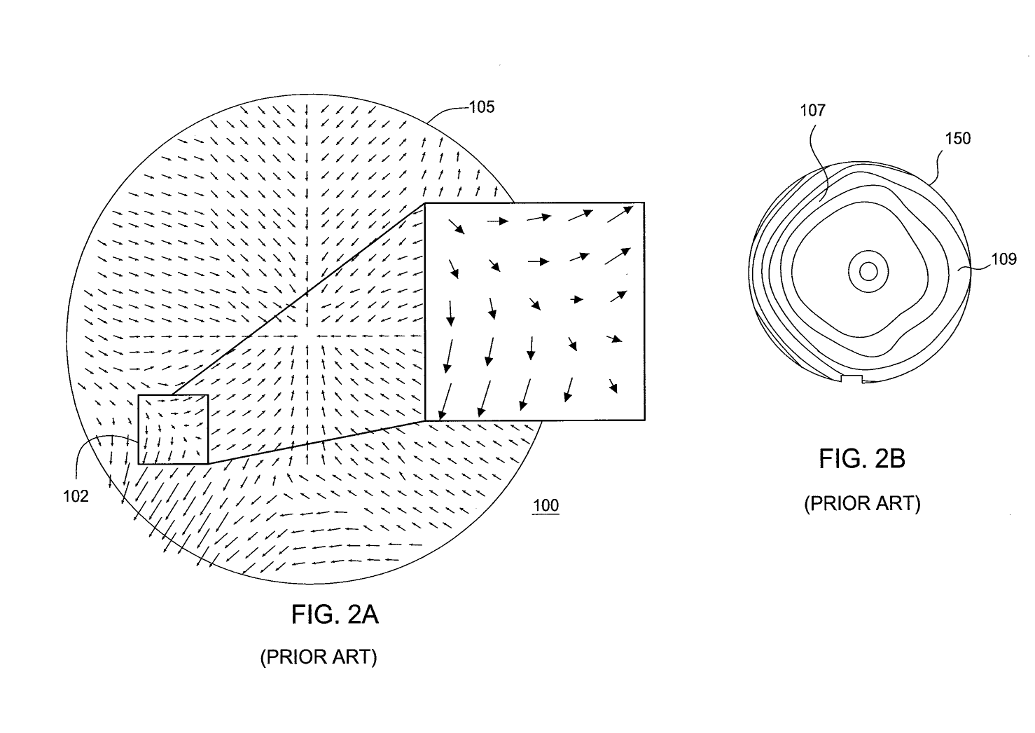

The process 900 starts at block 902 by performing a measurement process on a semiconductor substrate to obtain a substrate deformation data, substrate stress data, or overlay error data from the semiconductor substrate. The substrate deformation data, substrate stress data, or overlay error data may be obtained by utilizing a metrology tool, such as the metrology tool 810 incorporated in the system 800, to scan the semiconductor substrate to determine an overlay error map, such as the overlay error or stress profile map depicted in FIG. 2A or 2B, or substrate distortion. The overlay error map, such as the overlay error or stress profile map, may include a digital representation of the local curvature or stress related vectors at various points across the surface of the substrate, which can be stored in memory. Suitable metrology tools may include differential interferometer, a tunable vibration source, a non-contact dopier vibrometer, acoustic measurement, absolute interferometer, or deflection metrology tools. The metrology tool may be utilized to scan the semiconductor substrate and determine the overlay error map or substrate distortion. The metrology tool 810 may assist by providing information regarding the stress distribution, substrate curvature (including global substrate curvature or localized substrate curvature), substrate deformation and/or distortion of the substrate, so as to more precisely predict the surface topography or slope of the substrate surface. The metrology tool may be a metrology tool available from KLA-Tencor® of California. It is noted that other suitable metrology tools from other manufacturers may also be utilized to perform the scan and measurement process.

In one embodiment, the overlay error map or substrate distortion may be determined by measuring a film stress of the film layer (or stack of film layers) deposited on the semiconductor substrate. The deviation in the film stress distributed across the substrate surface may reflect the degree of overlay error or pattern displacement/shift present, or which may subsequently be present, on the substrate.

At block 904, after the data, e.g., the overlay error map or substrate distortion, is obtained from the metrology tool 810, the data may be received by a data computing system, such as the controller 490 incorporated in the system 800, for analysis. The data computing system may be stand-alone processor that is in communication with the controller 490 incorporated in the system 800. The data computing system determines a surface modification recipe to perform a surface modification process, such as an ion implantation process, on the film layer on the substrate in order to reduce overlay error in the processing chambers 804, 806, 808. In another embodiment, the data computing system may be integrated in the metrology tool 810 in the system 800 so as to compare, compute and analyze the data as the substrate measurement process at block 902 is completed. In this embodiment, the data computing system integrated in the metrology tool 810 is configured to be in communication with the controller 490 of the processing chambers 804, 806, 808 (such as the processing chamber 400 depicted in FIG. 4) to assist computing/selecting a proper surface modification recipe.

The data computing system may compare the data obtained from the substrate measurement process at block 902 with the database library or algorithm stored in the data computing system so as to determine a surface modification recipe to be performed on the substrate. The surface modification recipe may include the information regarding the implantation dose, and/or energy and the locations on the substrate where the dopants are configured to be disposed. In other words, the surface modification recipe is generated based on the overlay error map or substrate distortion obtained by the metrology tool 810 in the block 602 after a sequence of calculation, comparison and computation by the data computing system using the database library or algorithm stored in the data computing system. The database library or algorithm stored in the data computing system may include a correlation regarding the ion implantation dose and/or required ion implantation energy that is needed for a certain film layer, which is then related to the local film stress or substrate curvature found on the substrate. In one example, based on different types of film profile or film materials present on the substrate, a dose profile (e.g., a center-to-edge profile or left/right stress correction profile) may be calculated utilizing the data base algorithm stored in the data computing system to correct substrate stress distribution or distortion in a known substrate manufacturing process (e.g., deposition process). In some examples where the film stress or film profile of a material layer is highly dependent on the type of chambers or process used to form such material layer, a pre-stored dose profile (e.g., a center-to-edge profile or left/right stress correction profile) in the data computing system may be jointly computed and calculated as one of the factors/parameters to correct a typical stress distribution as needed.

The surface modification process performed based on the surface modification recipe may alter, release or eliminate localized residual stress in discrete regions of the substrate based on the substrate measurement process performed at block 902, so as to locally change the in-plane strain, substrate curvature (or pattern shift) in the substrate. By doing so, a deformed substrate may be changed or modified (for example, straightened) and present substantially flat and/or uniform substrate and film profile across the substrate surface. The straightened features allow for reduced overlay errors in the subsequent lithographic exposure process, enhancing alignment precision during the lithographic exposure process. It is noted that when the deformation or curvature of the substrate occurs globally across the substrate surface, substrate clamping or restraining the substrate to a substrate support using a substrate holding device, such as an electrostatic chuck, may be utilized to assist flattening or straightened the substrate, so as to ease the substrate global curvature as needed.

At block 906, after the surface modification recipe is determined, a surface modification process, such as an ion implantation process, is then performed in the processing chambers 804, 806, 808 in the system 800. It is noted that other surface modification process, such as a laser process, an annealing process, ion doping process, or other suitable process may also be utilized. The substrate may be transferred from the metrology tool 810 to the processing chambers 804, 806, 808 (such as the processing chamber 400 depicted in FIG. 4) to perform the surface modification process based on the data and error map computed by the data computing system at block 904.

The surface modification process may alter or modify film properties of the film layer disposed on the substrate so as to alter the film stress/in-plane strain (or pattern shift, or substrate curvature) in the film layer by the ions implanted into the substrate so as to change the shape of the die grid and improve alignment precision for the subsequent lithographic exposure process.

It is noted that the film layer disposed on the substrate 502 that may undergo the surface modification process may be fabricated from a dielectric material selected from a group consisting of silicon nitride (Si₃N₄), silicon nitride hydride (SiₓN_{y}:H), amorphous carbon, silicon carbide, silicon oxide, silicon oxynitride, a composite film of silicon oxide, silicon nitride, silicon carbide or amorphous carbon, an aluminum oxide layer, a tantalum oxide layer, a titanium oxide layer, spin-cast organic polymers, or other suitable material. In another embodiment, film layer may be any suitable polymer organic material, including SOG, polyimide or any suitable materials.

After the surface modification process is performed, a post correction validation measurement process may be performed to ensure that the local stress and substrate curvature has been efficiently relieved and eliminated from the substrate. The post validation measurement process may be performed by transferring the substrate 502 back to the metrology tool 810 to re-measure and obtain overlay error map or substrate distortion of the substrate. Furthermore, the post validation measurement process may also apply its measurement result to the subsequent substrate that is processed in the processing chamber so that the pre-measurement process may be eliminated while correcting the substrate curvature and local stress profile as needed.

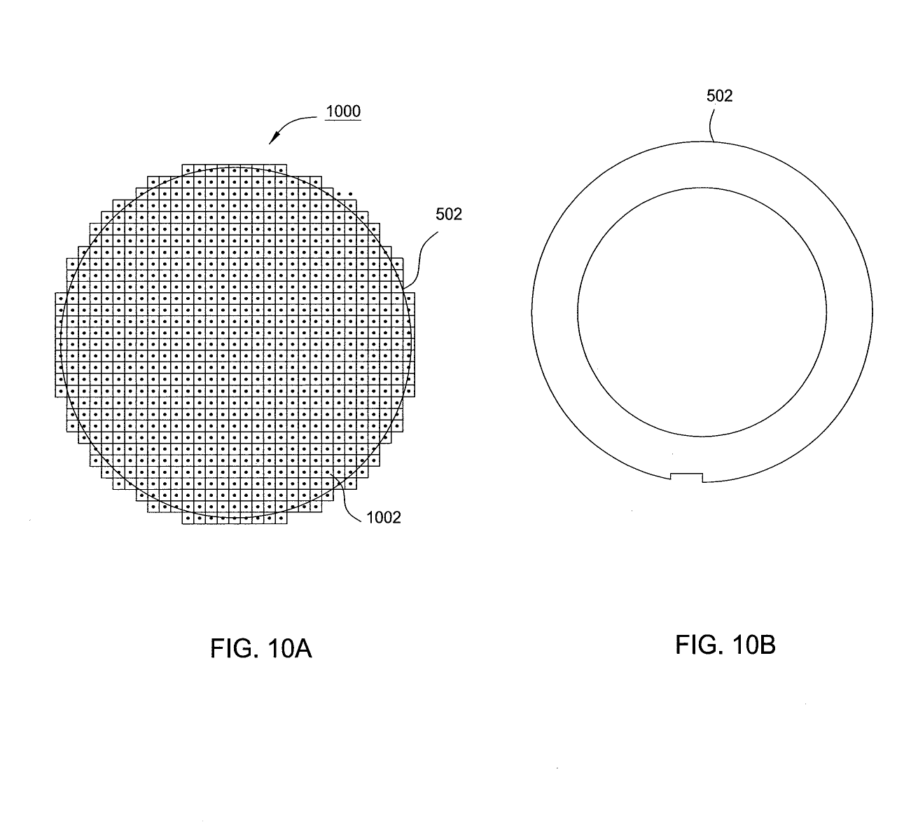

In an exemplary embodiment depicted in FIGS. 10A and 10B, after the semiconductor substrate is corrected by the surface modification process, such as an ion implantation process, the features of the device die are significantly displaced, alerted and corrected, as shown in FIG. 10A, as compared to the large displacement depicted in FIG. 2A prior to the surface modification process. The stress distribution profile shown in FIG. 10B is also substantially uniformly distributed, as compared to the stress profile in FIG. 2B prior to the surface modification process, so as to enhance alignment precision in the lithographic exposure process with minimum overlay errors.

In some embodiments, the processes performed in blocks 902-906 of the process 900 are repeated after performing a substrate manufacturing process step. In some embodiments, the processes performed in blocks 902-906 are performed during and/or after the a semiconductor wafer processing step is performed, which may include, but is not limited to, an atomic layer deposition (ALD) process, atomic layer etch (ALE) process, chemical vapor deposition (CVD) process, physical vapor deposition (PVD) process, implant process, thermal processing (e.g., laser anneal) process, rapid thermal anneal (RTA) process, lithographic process, exposure to EUV process, 193i process and multi-beam processes, and other similar processes.

Thus, embodiments of the disclosure provide an integrated system that includes a metrology tool and a processing chamber that can integrate the execution of a stress/overlay error measurement process followed by a surface modification process to correct the substrate curvature in a single integrated system. The stress/overlay correction process as performed may alter film stress/strain distribution in the film layer disposed on the semiconductor substrate as well as the semiconductor substrate curvature. By determining the amount of ion dose and location where the ions should be doped into to correct and alter film stress/substrate curvature in the film layers on the semiconductor substrate, the overlay error may be corrected and eliminated so as to increase alignment precision for the next lithographic exposure process.

While the foregoing is directed to embodiments of the present disclosure, other and further embodiments of the disclosure may be devised without departing from the basic scope thereof, and the scope thereof is determined by the claims that follow.

What is claimed is:

1. A processing system comprising:
at least a load lock chamber;
a transfer chamber coupled to the load lock chamber;
an ion implantation processing chamber coupled to the transfer chamber; and
a metrology tool coupled to or in the transfer chamber, wherein the metrology tool is adapted to obtain stress profile or an overlay error on a substrate disposed in the metrology tool.

2. The processing system of claim 1 further comprising:
a deposition chamber coupled to the transfer chamber.

3. The processing system of claim 1, further comprising:
a factory interface adapted to receive the substrate to be transferred through the load lock chamber to the transfer chamber when in process.

4. The processing system of claim 1, wherein the ion implantation process is adapted to perform a surface modification process to the substrate to correct stress profile or overlay error of the substrate.

5. A method for correcting stress profile or overlay error on a substrate, comprising:
performing a measurement process in a metrology tool disposed in a processing system on a substrate to obtain a substrate distortion or an overlay error map;
determining a surface modification recipe in a computing system based on the substrate distortion or overlay error map obtained from the measurement process in the processing system; and
performing an ion implantation process in a processing chamber disposed in the processing system to correct substrate distortion or overlay error on the substrate.

6. The method of claim 5, wherein the processing chamber is an ion implantation processing chamber.

7. The method of claim 5, wherein the processing chamber includes a beam source assembly.

8. The method of claim 5, wherein performing the ion implantation process further comprises:
generating an ion beam in the processing chamber to a predetermined location on the substrate based on the surface modification recipe from the metrology tool.

9. The method of claim 5, wherein determining the surface modification recipe in the computing system further comprises:
comparing the overlay error map or substrate distortion measured from the metrology tool with database library stored in the computing system.

10. The method of claim 6, wherein the database library includes a correlation of a stress change or overlay error of the substrate to an ion implantation dose required for correction.

11. The method of claim 5, wherein performing the ion implantation process in the processing chamber further comprises:
altering a film stress locally or globally on a film layer disposed on the substrate.

12. The method of claim 5, wherein performing the ion implantation process in the processing chamber further comprises:
correcting overlay error or substrate distortion found on the substrate.

13. The method of claim 5, wherein the surface modification recipe is determined in response to a film stress, substrate curvature, in plane distortion or pattern shift detected on the substrate.

14. The method of claim 5, wherein the computing system is incorporated in the metrology tool or in the processing chamber in the processing system.

15. A method for correcting overlay error on a substrate comprising:
measuring a film stress of a substrate disposed in a metrology tool in a processing system;
creating a correlation to the film stress behavior with a database library to determine an ion implantation recipe; and
performing an ion implantation process on selected discrete locations of the substrate using the determined ion implantation recipe in a processing chamber disposed in the processing system.

16. The method of claim 15, wherein performing ion implantation process further comprises:
locally altering a residual stress of the substrate which changes local curvature of the substrate.

17. The method of claim 15, wherein the metrology tool in the processing chamber is in data communication with the processing chamber disposed in the processing system.

18. The method of claim 15, wherein the database library includes a correlation of a stress change or overlay error of the substrate to an ion implantation dose required for correction.

19. The method of claim 15, wherein the processing chamber comprises a beam source assembly.

20. The method of claim 19, wherein the beam source assembly provides ion beams to the selected discrete locations of the substrate to implant ions thereto.
